(19) United States
(12) Patent Application Publication
(10) Pub. No.: US 2024/0206221 A1
(43) Pub. Date: Jun. 20, 2024

(54) METAL-OXIDE BLOCKING LAYERS DEPOSITED VIA ATOMIC LAYER DEPOSITION FOR ORGANIC LIGHT EMITTING DIODES

(71) Applicant: The Regents of the University of Michigan, Ann Arbor, MI (US)

(72) Inventors: Jeffrey A. Horowitz, Ann Arbor, MI (US); Claire Arneson, Ann Arbor, MI (US); Stephen R. Forrest, Ann Arbor, MI (US)

(21) Appl. No.: 18/539,591

(22) Filed: Dec. 14, 2023

Related U.S. Application Data
(60) Provisional application No. 63/476,339, filed on Dec. 20, 2022.

(51) Int. Cl. H10K 50/18; H10K 50/13

(52) U.S. Cl. CPC H10K 50/18; H10K 50/13; H10K 2102/351

(57) ABSTRACT

In one aspect, an organic light emitting device (OLED) comprises a first electrode, a second electrode, an emissive layer between the first and second electrodes, and a blocking layer comprising metal oxide between the emissive layer and the first electrode. In some embodiments, the OLED is configured as a white OLED. In some embodiments, the emissive layer comprises a stack of a plurality of sub-layers. In some embodiments, the blocking layer is deposited via an atomic layer deposition (ALD) tool. In some embodiments, the blocking layer comprises HfO₂, Al₂O₃, ZrO₂, ZnO, or MgO.

### CROSS-REFERENCE TO RELATED APPLICATIONS

This application claims priority to U.S. provisional application No. 63/476,339 filed on Dec. 20, 2022, incorporated herein by reference in its entirety.

### STATEMENT REGARDING FEDERALLY SPONSORED RESEARCH OR DEVELOPMENT

This invention was made with government support under DE-EE0008723 awarded by the U.S. Department of Energy. The government has certain rights in the invention.

### BACKGROUND OF THE INVENTION

Phosphorescent organic light-emitting diodes (OLEDs) possess many advantages, including high-efficiency operations, a tunable spectrum, and the potential for high-yield and long-lifetime devices. White phosphorescent OLEDs (WOLEDs) are therefore a serious candidate for large-scale, solid-state lighting. A stacked WOLED structure employs three separate emissive layers, producing white light through the combination of three parts of the visible spectrum (e.g., red, green, and blue). Stacked WOLEDs have achieved a color rendering index as high as 89. By tuning the emission of each of these three regions, the color of the WOLED can be tuned to the desired color temperature and color coordinates for white light. However, as the injected current increases, the exciton formation zone drifts within the device, leading to a color shift at higher brightness. This is due to a charge imbalance in the active regions, an effect which becomes more pronounced as the current increases. Excess holes, for example, do not recombine in the desired emissive region, but rather the following region, emitting a different color. Therefore, it is necessary to employ blocking layers to maintain a stable charge balance across a range of injection currents.

### SUMMARY OF THE INVENTION

Some embodiments of the invention disclosed herein are set forth below, and any combination of these embodiments (or portions thereof) may be made to define another embodiment.

In one aspect, an organic light emitting device (OLED) comprises a first electrode, a charge transport layer above the first electrode, a blocking layer comprising metal oxide above the charge transport layer, an emissive layer above the blocking layer, and a second electrode above the emissive layer.

In one embodiment, the OLED is configured as a white OLED.

In one embodiment, the emissive layer comprises a stack of a plurality of sub-layers.

In one embodiment, the plurality of sub-layers comprise a green emissive sub-layer, a red emissive sub-layer, and a blue emissive sub-layer.

In one embodiment, the green emissive sub-layer has a thickness of 5 nm and comprises Ir(ppy)3:mCBP, the red emissive sub-layer has a thickness of 10 nm and comprises PQIr:mCBP, and the blue emissive sub-layer has a thickness of 10 nm and comprises Ir(iprpmi)3:mCBP.

In one embodiment, the blocking layer is deposited via an atomic layer deposition (ALD) tool.

In one embodiment, the blocking layer comprises HfO₂, Al₂O₃, ZrO₂, ZnO, or MgO.

In one embodiment, the blocking layer comprises a 2D layer and/or monolayer.

In one embodiment, the blocking layer has a roughness of less than 0.5 nm.

In one embodiment, the blocking layer has a thickness less than 5 nm.

In one embodiment, the OLED further comprises a buffer layer between the blocking layer and the first electrode.

In one embodiment, the buffer layer is adjacent to the blocking layer.

In one embodiment, the buffer layer comprises MoOₓ.

In one embodiment, the blocking layer comprises a wide-bandgap material.

In one embodiment, the blocking layer has a valence band of −7 eV or deeper.

In one embodiment, the blocking layer has a valence band of −9 eV or deeper.

In one embodiment, the OLED further comprises a second blocking layer between the emissive layer and the second electrode, comprising a metal oxide.

In another aspect, an organic light emitting device (OLED), comprises a first electrode, a MoOₓ buffer layer above the first electrode, a 2D blocking layer comprising metal oxide formed via atomic layer deposition (ALD) above and adjacent to the MoOₓ buffer layer, an emissive layer above the blocking layer and a second electrode above the emissive layer.

In one embodiment, the OLED is configured as a white OLED.

In one embodiment, the blocking layer comprises HfO₂, Al₂O₃, ZrO₂, ZnO, or MgO.

In another aspect, a method of manufacturing an organic light emitting device (OLED) comprises depositing a first electrode, depositing a blocking layer comprising metal oxide above the first electrode via atomic layer deposition (ALD), depositing an emissive layer above the blocking layer, and depositing a second electrode above the emissive layer.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1 is a block diagram depicting an exemplary organic light emitting device (OLED) in accordance with some embodiments.

FIG. 2 is a block diagram depicting an exemplary inverted organic light emitting device that does not have a separate electron transport layer in accordance with some embodiments.

FIG. 3 depicts an energy level diagram for the organic semiconductor materials in a WOLED in accordance with some embodiments.

FIG. 4 depicts an energy level diagram for ALD-deposited metal oxide materials compared to CBP in accordance with some embodiments.

FIG. 5 exemplary OLED structures comprising an ALD metal oxide blocking layer in accordance with some embodiments. mCBP is the host for all three emission layers.

FIG. 6 depicts spectra at varying current densities for the devices in FIG. 5 in accordance with some embodiments.

FIG. 7 depicts current density and EQE properties of experimental devices including ALD metal oxide blocking layers comprising various materials in accordance with some embodiments.

FIG. 8 depicts Al₂O₃ growth on NPD in accordance with some embodiments.

FIG. 9 depicts Al₂O₃ growth on Si in accordance with some embodiments.

FIG. 10 is a plot depicting X-ray photoelectron spectroscopy of Al₂O₃ and NPD+Al₂O₃ at 40° C. and 80° C. in accordance with some embodiments.

FIG. 11 shows detailed views of the O 1s and Al 2p peaks of the plots of FIG. 10 in accordance with some embodiments.

FIGS. 12A-12D show experimental performance results comparing devices utilizing Tris-PCz and Al₂O₃ blockers in accordance with some embodiments. FIG. 12A shows the experimental device structures and energy levels, FIG. 12B is a plot showing device lifetime at 1000 nits, FIG. 12C is a plot showing J-V characteristics, and FIG. 12D is a plot showing EQE vs Current Density.

FIGS. 13A-13C are plots showing experimental results for devices based on increasing Al₂O₃ blocking layer thickness in accordance with some embodiments. FIG. 13A is a plot showing J-V characteristics, FIG. 13B is a plot showing EQE vs Current Density, and FIG. 13C is a plot showing device lifetime at 1000 nits.

FIGS. 14A-14D are plots of J-V characteristics (FIG. 14A, FIG. 14C) and EQE vs Current Density (FIG. 14B, FIG. 14D) comparing experimental performance of devices utilizing TrisPCZ (FIGS. 14A-14B) and Al₂O₃(FIGS. 14C-14D) blocking layers in accordance with some embodiments.

FIG. 15 depicts growth of Al₂O₃ on MoOₓ at 40° C. in accordance with some embodiments.

FIGS. 16A-16H depict details of experimental solution processed OLEDs with USC TADF dopant in accordance with some embodiments. FIGS. 16A-16B depict details of the devices, FIG. 16C is a plot depicting experimental current density for a control device, FIG. 16D us a plot depicting experimental luminance for the control device, FIG. 16E is a plot depicting EQE vs. Current Density for the control device, FIG. 16F is a spectrum plot for the control device, and FIGS. 16G-16H depict current density and luminance, respectively, for a device including a 2 nm ALD AL₂O₃ metal oxide blocking layer.

### DETAILED DESCRIPTION OF THE INVENTION

It is to be understood that the figures and descriptions of the present invention have been simplified to illustrate elements that are relevant for a clearer comprehension of the present invention, while eliminating, for the purpose of clarity, many other elements found in systems and methods of metal-oxide blocking layers deposited via atomic layer deposition for organic light emitting diodes (OLED). Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, and ±0.1% from the specified value, as such variations are appropriate.

Ranges: throughout this disclosure, various aspects of the invention can be presented in a range format. It should be understood that the description in range format is merely for convenience and brevity and should not be construed as an inflexible limitation on the scope of the invention. Where appropriate, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, and 6. This applies regardless of the breadth of the range.

Referring now in detail to the drawings, in which like reference numerals indicate like parts or elements throughout the several views, in various embodiments, presented herein is metal-oxide blocking layers deposited via atomic layer deposition for organic light emitting diodes (OLED).

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

As used herein, and as would be understood by one skilled in the art, “HATCN” (referred to interchangeably as HAT-CN) refers to 1,4,5,8,9,11-Hexaazatriphenylenehexacarbonitrile.

“TAPC” refers to 4,4′-Cyclohexylidenebis[N,N-bis(4-methylphenyl)aniline]. “B3PYMPM” refers to 4,6-Bis(3,5-di(pyridin-3-yl)phenyl)-2-methylpyrimidine. “BPyTP2” refers to 2,7-Bis(2,2′-bipyridin-5-yl)triphenylene. “LiQ” refers to Lithium Quinolate. “ITO” refers to Indium Tin Oxide. “CBP” refers to 4,4′-Bis(N-carbazolyl)-1,1′-biphenyl. “Ir(ppy)2acac” refers to bis[2-(2-pyridinyl-N)phenyl-C](acetylacetonato)iridium(III).

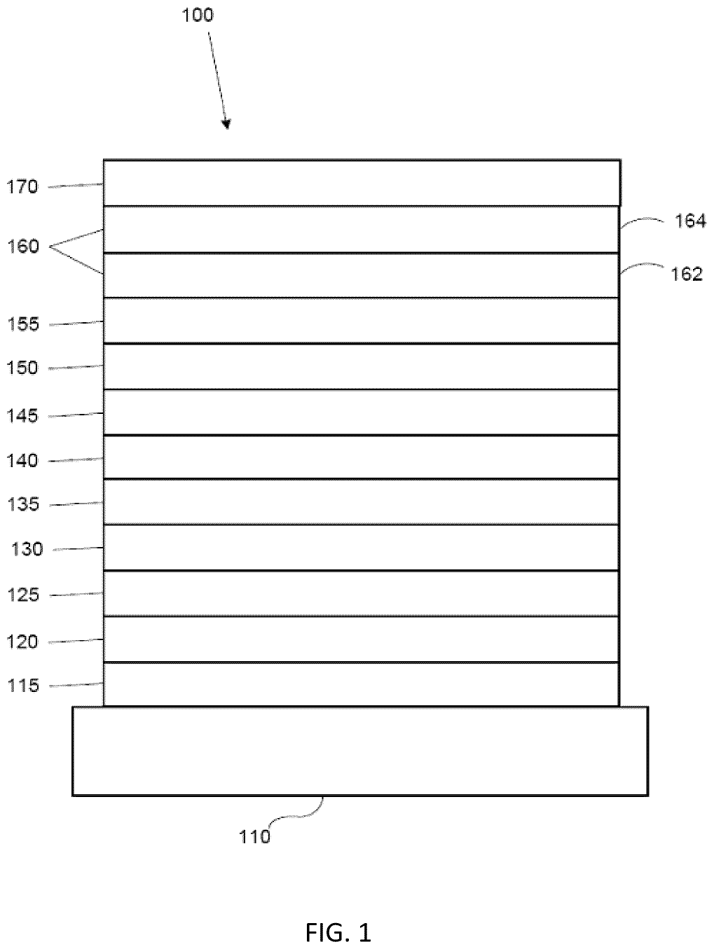

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F4-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

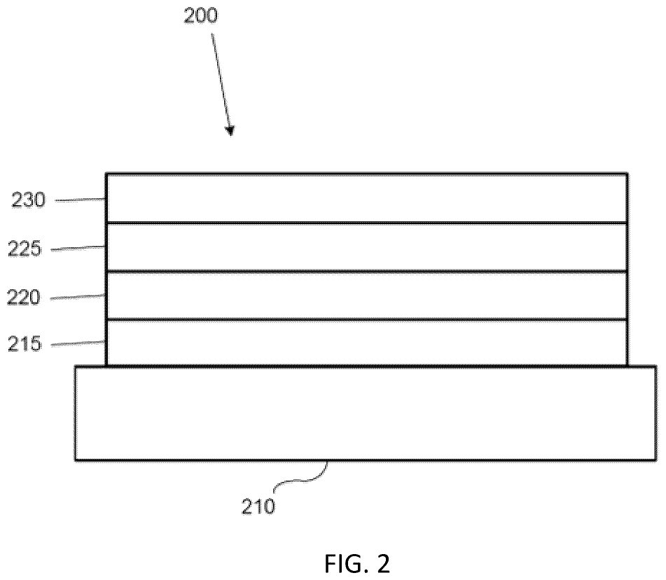

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIG. 1 and FIG. 2 is provided by way of non-limiting example, and it is understood that embodiments of the disclosure may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Although certain embodiments of the disclosure are discussed in relation to one particular device or type of device (for example OLEDs) it is understood that the disclosed improvements to light outcoupling properties of a substrate may be equally applied to other devices, including but not limited to PLEDs, OPVs, charge-coupled devices (CCDs), photosensors, or the like.

Certain embodiments of the disclosure relate to a light emitting device comprising an emissive layer (EML) spaced far from a cathode as described herein. Conventional organic light emitting devices typically place the EML near a metal cathode which incurs plasmon losses due to near field coupling. To avoid exciting these lossy modes it is necessary to space the EML far from the cathode. However, utilizing a thick electron transport layer (ETL) can be problematic due to changes in charge balance and increased resistivity. These problems can be overcome by utilizing a charge generation layer, for example a charge generation layer comprising at least one electron transport layer and at least one hole transport layer, to convert electron into hole current. This allows the use of higher mobility hole transporting materials and maintains the charge balance of the device. In some embodiments, the charge generation layer may be replaced or combined with any other layer capable of conducting electrons.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, computer monitors, medical monitors, televisions, billboards, lights for interior or exterior illumination and/or signaling, heads-up displays, fully or partially transparent displays, flexible displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, and a sign. Various control mechanisms may be used to control devices fabricated in accordance with the present invention, including passive matrix and active matrix. Many of the devices are intended for use in a temperature range comfortable to humans, such as 18° C. to 30° C., and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

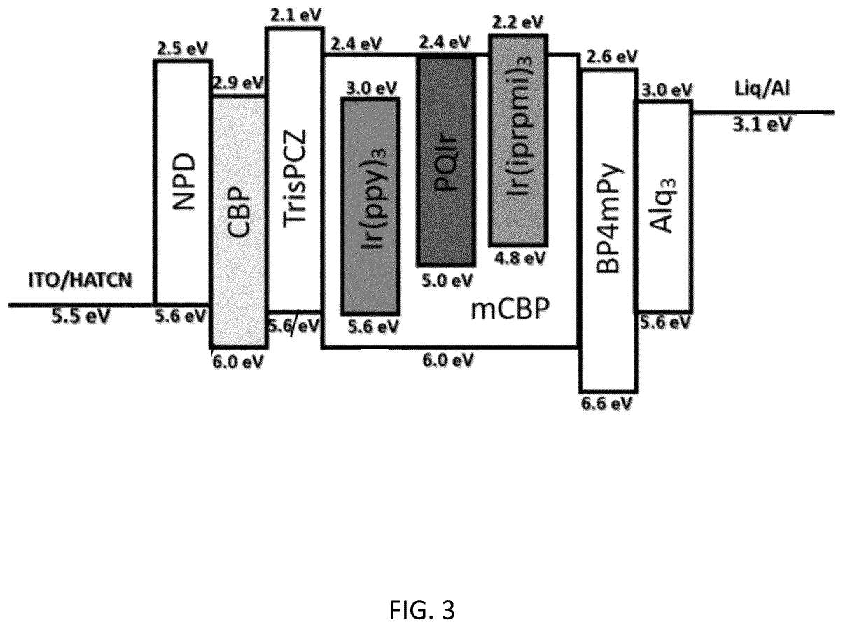

Referring now to FIG. 3, energy levels in organic semiconductors are characterized by their highest occupied molecular orbitals (HOMOs) and their lowest unoccupied molecular orbitals (LUMOs). Referenced to the vacuum level, a “deep” energy level is more negative than a “shallow” energy level. Electrons are blocked by a shallow LUMO, while holes are blocked by a deep HOMO. FIG. 3 shows energy levels for a typical stacked WOLED structure, with the inclusion of an organic vacuum-deposited blocking layer. Thus, through the careful selection of materials, charge balance can be improved within WOLEDs.

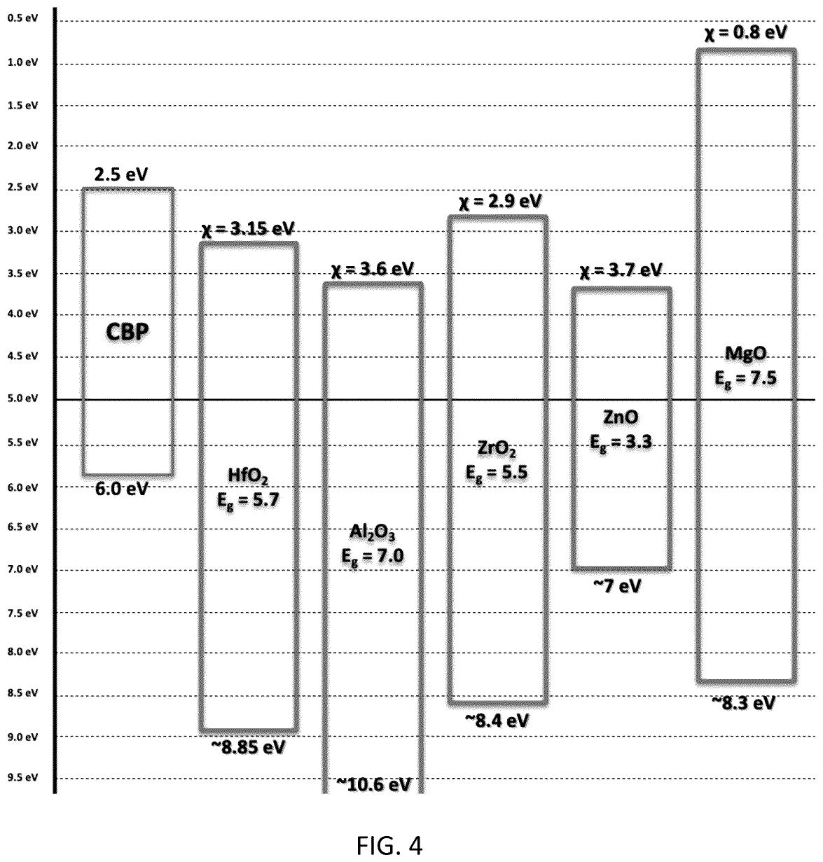

Further disclosed herein is an atomic layer deposition tool (ALD) to deposit metal-oxides as blocking layers for WOLEDs. Al₂O₃ is a wide-bandgap material with a deep valence band of about −9 to −10 eV. Most organic materials have a shallower HOMO, so Al₂O₃ can be used as a blocking layer. For ZrO₂, the valence band is also deep. Both Al₂O₃ and ZrO₂ are readily deposited in the ALD tool using trimethylaluminum (TMA) and water as the precursors for Al₂O₃ and tetrakis(dimethylamino)zirconium (TDMAZ) and water for ZrO₂. HfO₂ is another candidate material for hole-blocking. Energy levels for these materials are shown in FIG. 4.

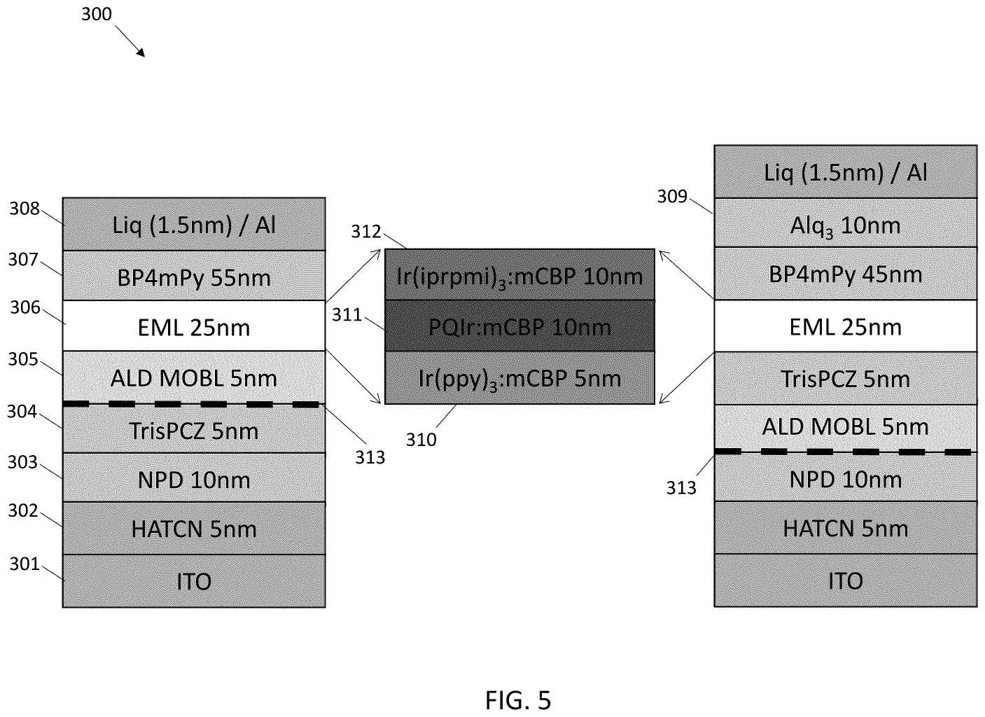

While many metal oxides have deep valence bands, some, for example MoO₃ and ZnO, also contain deep conduction bands. These materials are likely to act as electron traps and are therefore unsuitable for this application. FIG. 5 shows example OLED device 300 structures including an ALD metal oxide blocking layer (ALD MOBL) 305. The layers of the OLED 300 (electrode, emissive layer, HBL, HTL, EBL, ETL, . . . ) may each have any suitable thickness, including but not limited to any value within the range of 0.01 nm to 1 cm, and suitable materials.

In some embodiments, an organic light emitting device (OLED) 300 comprises a first electrode 301, a metal oxide blocking layer 305 above the first electrode and/or a charge transport layer, an emissive layer 306 above the metal oxide blocking layer 305, and a second electrode 308 above the emissive layer 306.

In some embodiments, the OLED 300 is configured as a white OLED. In some embodiments, the emissive layer 306 comprises a stack of a plurality of sub-layers. In some embodiments, the plurality of sub-layers comprise a green emissive sub-layer 310, a red emissive sub-layer 311, and a blue emissive sub-layer 312. In some embodiments, the green emissive sub-layer 310 has a thickness of about 5 nm and comprises Ir(ppy)3:mCBP, the red emissive sub-layer 311 has a thickness of about 10 nm and comprises PQIr:mCBP, and the blue emissive sub-layer 312 has a thickness of about 10 nm and comprises Ir(iprpmi)3:mCBP, but any suitable thicknesses and materials can be utilized for the sub-layers.

In some embodiments, the metal oxide blocking layer 305 is deposited via an atomic layer deposition (ALD) tool and method. In some embodiments, the metal oxide blocking layer 305 comprises HfO₂, Al₂O₃, ZrO₂, ZnO, or MgO. In some embodiments, the metal oxide blocking layer 305 comprises a 2D layer and/or monolayer. In some embodiments, the metal oxide blocking layer 305 is a neat layer. In some embodiments, the metal oxide blocking layer 305 has a roughness of less than 1 nm, less than 0.5 nm, and/or less than 0.3 nm. In some embodiments, the metal oxide blocking layer 305 has a thickness less than 10 nm, less than 5 nm, and/or less than 3 nm.

In some embodiments, the OLED 300 further comprises an optional buffer layer 313 between the metal oxide blocking layer 305 and the first electrode 301. In some embodiments, the buffer layer 313 is adjacent to the metal oxide blocking layer 305. In some embodiments, the buffer layer 313 comprises MoOₓ.

In some embodiments, the metal oxide blocking layer 305 comprises a wide-bandgap material. In some embodiments, the metal oxide blocking layer 305 has a valence band of −7 eV or deeper, −8 eV or deeper, −9 eV or deeper, and/or −10 eV or deeper.

In some embodiments, the first electrode 301 comprises an anode and thus the metal oxide blocking layer 305 is positioned between the emissive layer 306 and the anode. In some embodiments, the first electrode 301 comprises a cathode and thus the metal oxide blocking layer 305 is positioned between the emissive layer 306 and the cathode.

In some embodiments, the OLED 300 further includes a second metal oxide blocking layer on the opposite side of the emissive layer 306 from the first blocking layer 305. In some embodiments, the second metal oxide blocking layer is positioned between the emissive layer 306 and the second electrode 308.

In some embodiments, the second metal oxide blocking layer is deposited via an atomic layer deposition (ALD) tool and method. In some embodiments, the second metal oxide blocking layer comprises HfO₂, Al₂O₃, ZrO₂, ZnO, or MgO. In some embodiments, the second metal oxide blocking layer comprises a 2D layer and/or monolayer. In some embodiments, the second metal oxide blocking layer is a neat layer. In some embodiments, the second metal oxide blocking layer has a roughness of less than 1 nm, less than 0.5 nm, and/or less than 0.3 nm. In some embodiments, the second metal oxide blocking layer has a thickness less than 10 nm, less than 5 nm, and/or less than 3 nm.

In some embodiments, the OLED 300 further comprises an optional second buffer layer between the second metal oxide blocking layer and the second electrode 308. In some embodiments, the second buffer layer is adjacent to the second metal oxide blocking layer. In some embodiments, the second buffer layer comprises MoOₓ.

In some embodiments, the second metal oxide blocking layer comprises a wide-bandgap material. In some embodiments, the second metal oxide blocking layer has a valence band of −7 eV or deeper, −8 eV or deeper, −9 eV or deeper, and/or −10 eV or deeper.

In some embodiments, the first electrode 301 comprises ITO. In some embodiments, the second electrode 308 comprises Al. In some embodiments, the second electrode 308 comprises Liq (1.5 nm)/AI.

In some embodiments, the OLED 300 further comprises a buffer layer 302. In some embodiments, the buffer layer 302 has a thickness of 1 nm to 20 nm, 2 nm to 10 nm, about 5 nm, or any other suitable thickness. In some embodiments, the buffer layer 302 comprises HATCN or any other suitable material.

In some embodiments, the OLED 300 further comprises a hole transport layer (HTL) 303. In some embodiments, the HTL 303 has a thickness of 1 nm to 20 nm, 5 nm to 15 nm, about 10 nm, or any other suitable thickness. In some embodiments, the HTL 303 comprises NPD or any other suitable material.

In some embodiments, the OLED 300 further comprises an electron blocking layer (EBL) 304. In some embodiments, the EBL 304 has a thickness of 1 nm to 20 nm, 2 nm to 10 nm, about 5 nm, or any other suitable thickness. In some embodiments, the EBL 304 comprises TrisPCZ or any other suitable material.

In some embodiments, the OLED 300 further comprises a hole blocking layer (HBL) 307. In some embodiments, the HBL 307 has a thickness of 1 nm to 100 nm, 25 nm to 75 nm, 40 nm to 60 nm, about 55 nm, about 45 nm, or any other suitable thickness. In some embodiments, the HBL 307 comprises BP4mPy or any other suitable material.

In some embodiments, the OLED 300 further comprises an electron transport layer (ETL) 309. In some embodiments, the ETL 309 has a thickness of 1 nm to 20 nm, 5 nm to 15 nm, about 10 nm, or any other suitable thickness. In some embodiments, the ETL 309 comprises Alq₃ or any other suitable material.

In some embodiments, a method of manufacturing an organic light emitting device (OLED) 300 comprises depositing a first electrode 301, depositing a metal oxide blocking layer 305 above the first electrode 301 via atomic layer deposition (ALD), depositing an emissive layer 306 above the metal oxide blocking layer 305, and depositing a second electrode 308 above the emissive layer 306.

The insertion of a metal-oxide blocking layer has three effects on the stacked WOLED devices. First, improved charge balance minimizes the shift in the exciton formation zone and therefore decreases the spectrum change which accompanies increasing currents. Second, the external quantum efficiency (EQE) (i.e., the number of photons emitted per injected electron) increases. Third, device lifetime improves.

Devices of the present disclosure may comprise one or more electrodes, some of which may be fully or partially transparent or translucent. In some embodiments, one or more electrodes comprise indium tin oxide (ITO) or other transparent conductive materials. In some embodiments, one or more electrodes may comprise flexible transparent and/or conductive polymers.

Layers may include one or more electrodes, organic emissive layers, electron- or hole-blocking layers, electron- or hole-transport layers, buffer layers, or any other suitable layers known in the art. In some embodiments, one or more of the electrode layers may comprise a transparent flexible material. In some embodiments, both electrodes may comprise a flexible material and one electrode may comprise a transparent flexible material.

An OLED fabricated using devices and techniques disclosed herein may have one or more characteristics selected from the group consisting of being flexible, being rollable, being foldable, being stretchable, and being curved, and may be transparent or semi-transparent. In some embodiments, the OLED further comprises a layer comprising carbon nanotubes.

In some embodiments, an OLED fabricated using devices and techniques disclosed herein further comprises a layer comprising a delayed fluorescent emitter. In some embodiments, the OLED comprises a RGB pixel arrangement or white plus color filter pixel arrangement. In some embodiments, the OLED is a mobile device, a handheld device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

An OLED fabricated according to techniques and devices disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL

A hole injecting/transporting material to be used in the present disclosure is not particularly limited, and any compound may be used as long as the compound is typically used as a hole injecting/transporting material.

### EBL

An electron blocking layer (EBL) may be used to reduce the number of electrons and/or excitons that leave the emissive layer. The presence of such a blocking layer in a device may result in substantially higher efficiencies, and/or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host

The light emitting layer of the organic EL device of the present disclosure preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

The CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

As previously disclosed, OLEDs and other similar devices may be fabricated using a variety of techniques and devices. For example, in OVJP and similar techniques, one or more jets of material is directed at a substrate to form the various layers of the OLED.

### EXPERIMENTAL EXAMPLES

The invention is now described with reference to the following Examples. These Examples are provided for the purpose of illustration only and the invention should in no way be construed as being limited to these Examples, but rather should be construed to encompass any and all variations which become evident as a result of the teaching provided herein.

Without further description, it is believed that one of ordinary skill in the art can, using the preceding description and the following illustrative examples, make and utilize the present invention and practice the claimed methods. The following working examples therefore, specifically point out exemplary embodiments of the present invention, and are not to be construed as limiting in any way the remainder of the disclosure.

WOLEDs are normally prepared using an evaporation chamber held at a pressure less than 10⁻⁶ torr. Here, the hole transport layer was deposited onto ITO-patterned glass in an evaporation chamber, and then the samples were sealed in nitrogen and transferred to the ALD for the deposition of a metal oxide. The samples were then sealed again in nitrogen and transferred back to the evaporation chamber for the deposition of the remaining layers. The ALD process is performed at temperatures of about 80° C. so as not to damage the organic layers.

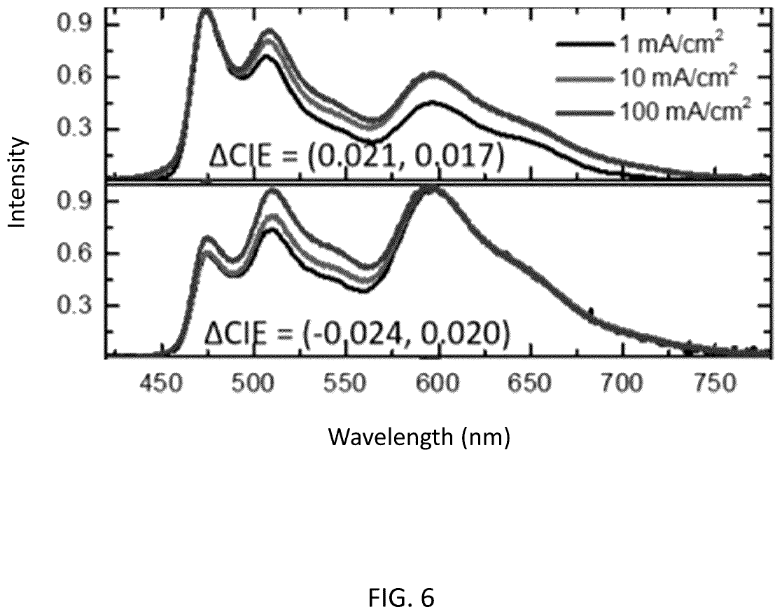

Al₂O₃ was grown with a 0.015 second pulse of H₂O followed by a 10 second purge, and then a 0.015 second pulse of TMA followed by a 10 second purge. ZrO₂ was grown with a 0.015 second pulse of H₂O followed by a 30 second purge, and then a 0.25 second pulse of TDMAZ followed by a 30 second purge. Each cycle grows less than a monolayer, so several cycles are performed for a thin layer. Alucone and Zircone may also be grown with this process simply by replacing the H₂O precursor with ethylene glycol. As shown in FIG. 6, the blocking layers 305 stabilize the spectrum of WOLEDs at different current densities.

Further experiments were conducted to further investigate ALD metal oxides as blocking layers. Atomic layer deposition (ALD) creates ultra-thin, uniform, pinhole-free, conformal layers. Furthermore, ALD can be done at very low temperatures and thus is compatible with organic materials with typically small glass transition temperature T_{g}.

It is known that organic blocking layers can be used to improve the charge balance and color stability. ALD deposited metal oxides can serve the same purpose. Depending upon their conduction band/valence band levels, ALD deposited ultra-thin metal oxides can selectively block holes/electrons/both to achieve desired exciton distribution. Furthermore, inorganic layers being inherently more stable than organic layers could potentially increase the lifetime of these devices.

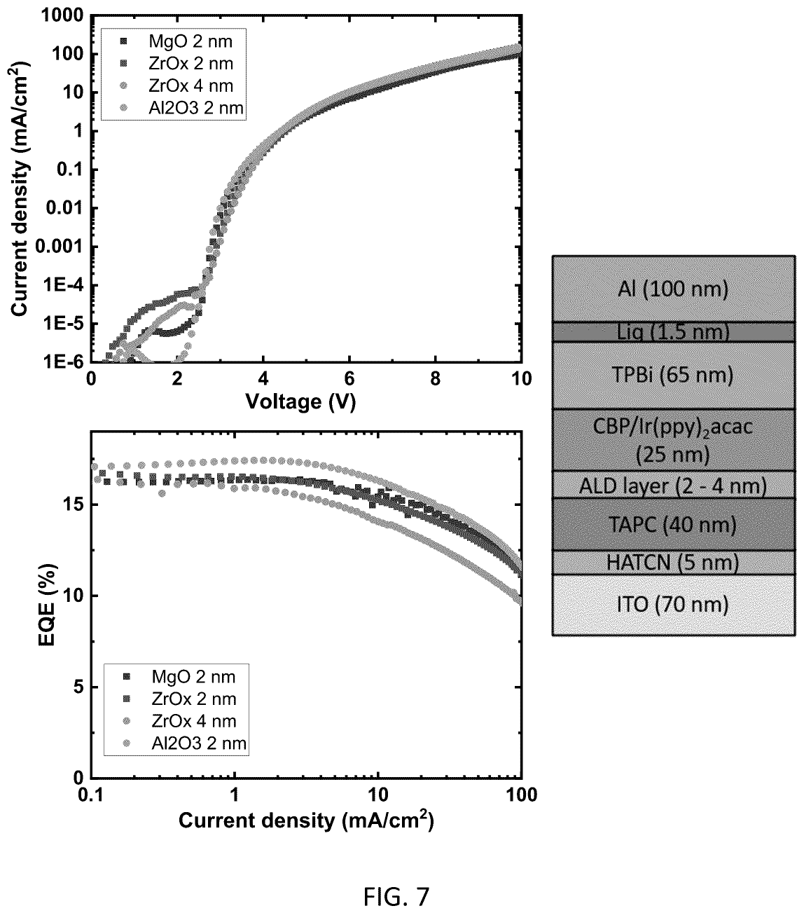

FIG. 7 depicts current density and EQE properties of experimental green OLEDs including ALD metal oxide blocking layers comprising various materials. Wide bandgap ALD metal oxides were initially explored including MgO 2 nm, ZrOx 2 nm, ZrOx 4 nm, and Al₂O₃ 2 nm, and Al₂O₃ showed the most reduction in leakage current and hence the highest EQE.

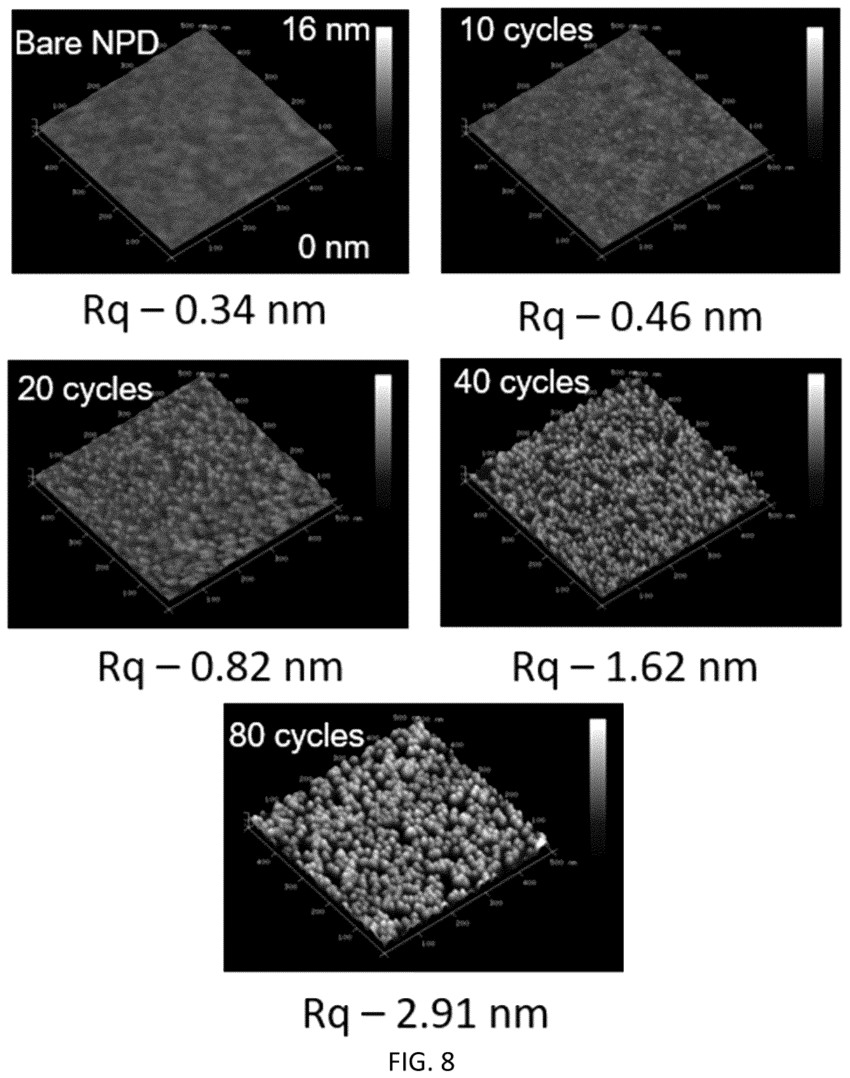

FIG. 8 depicts Al₂O₃ growth on NPD for bare NPD, after 10 ALD cycles, after 20 ALD cycles, after 40 ALD cycles, and after 80 ALD cycles. Al₂O₃ grew as 3D island on the organic HTL (NPD) due to incomplete nucleation leading to a significant rise in surface roughness.

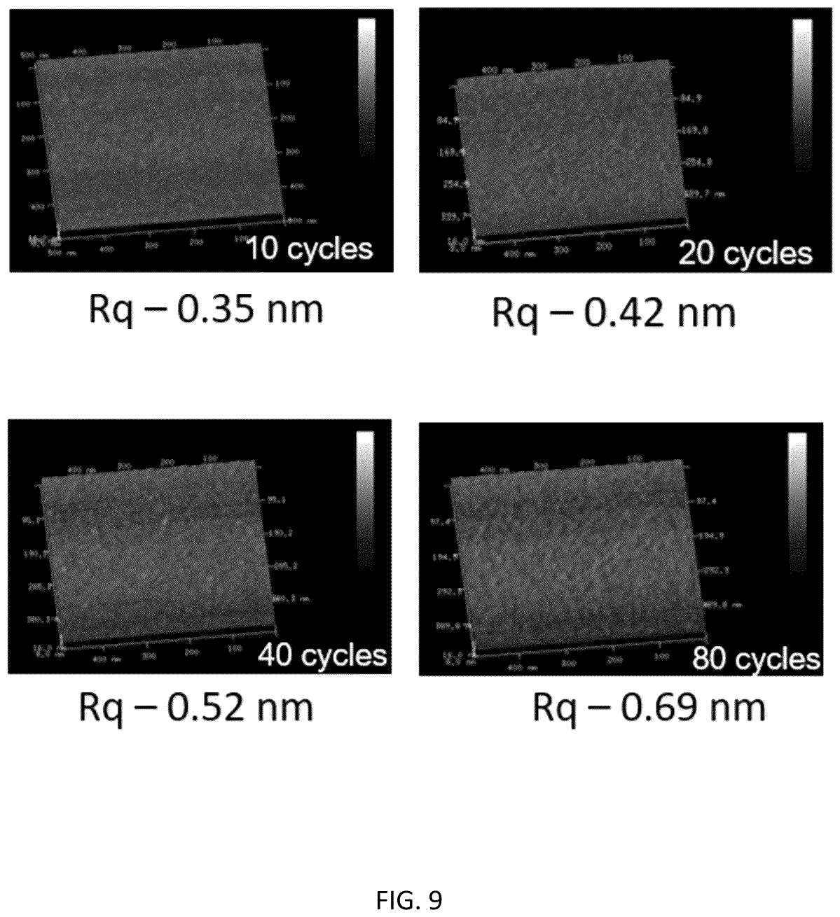

FIG. 9 depicts Al₂O₃ growth on Si after 10 ALD cycles, after 20 ALD cycles, after 40 ALD cycles, and after 80 ALD cycles. Al₂O₃ grew as a uniform 2D layer on top of the Si with negligible increase in the surface roughness.

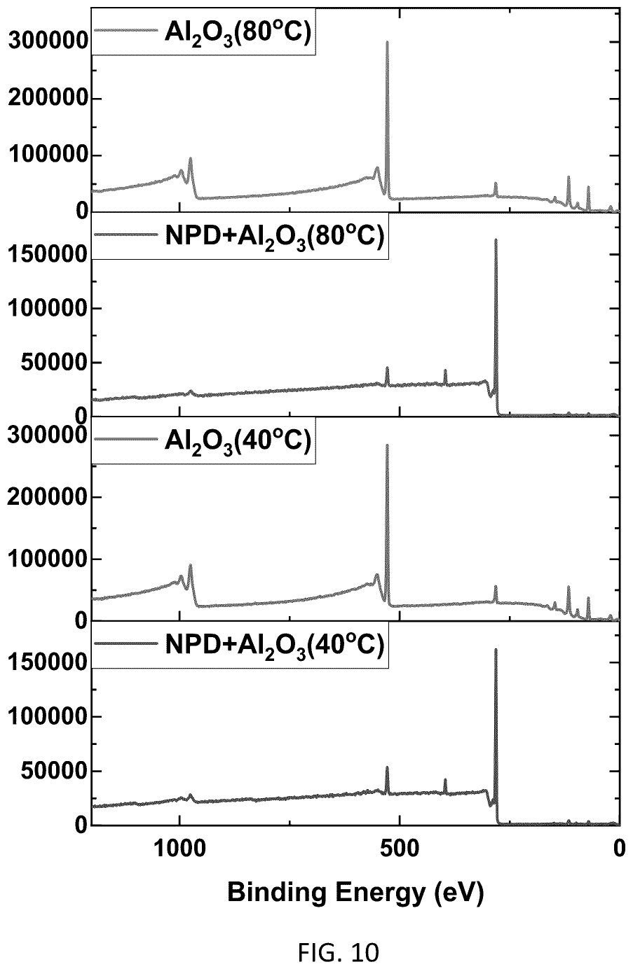

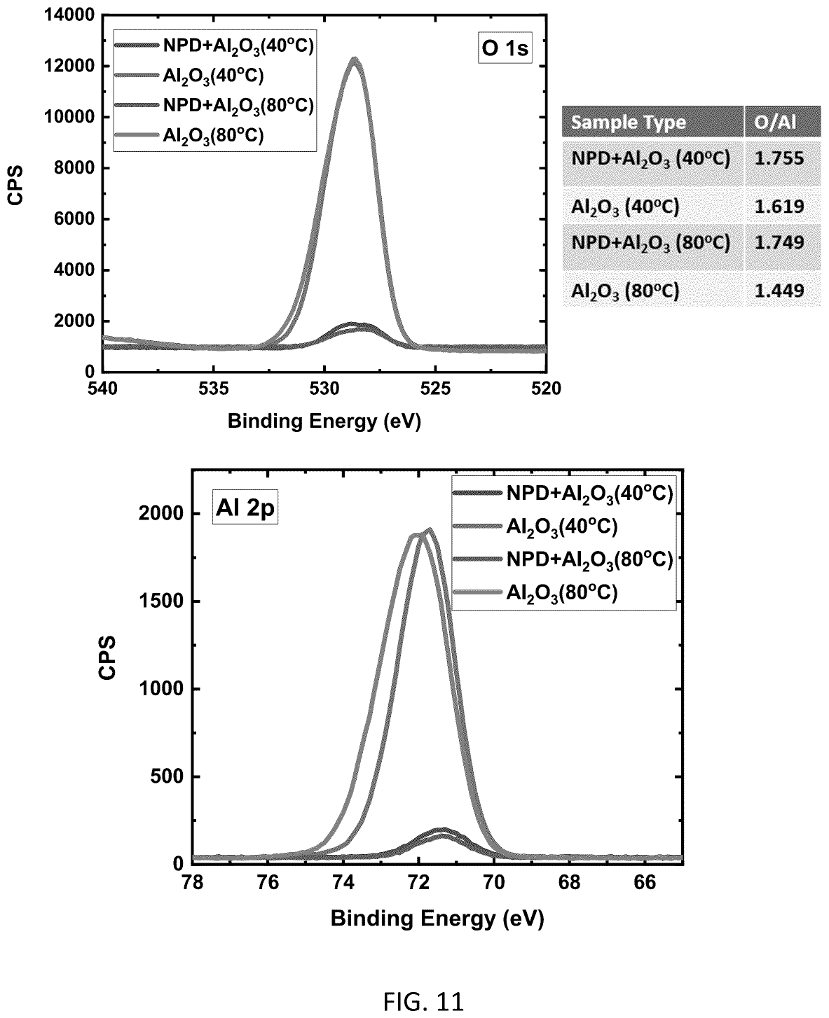

FIG. 10 is a plot depicting X-ray photoelectron spectroscopy of Al₂O₃ and NPD+Al₂O₃ at 40° C. and 80° C., and FIG. 11 shows detailed views of the O 1s and Al 2p peaks of the plots of FIG. 10. On Si, at 80° C., Al₂O₃ forms in almost exact stoichiometry. Reducing the temperature to 40° C. results in an increase in oxygen content due to incomplete reaction between TMA and H₂O precursors. On organic HTL NPD Al₂O₃ had significantly higher oxygen content, which may be due to absorption of H₂O molecules by organics. This composition did not change with reduction in temperature. Note, the lower signal strength from Al₂O₃ on organics is due to electrons lost to scattering due to the rough surface.

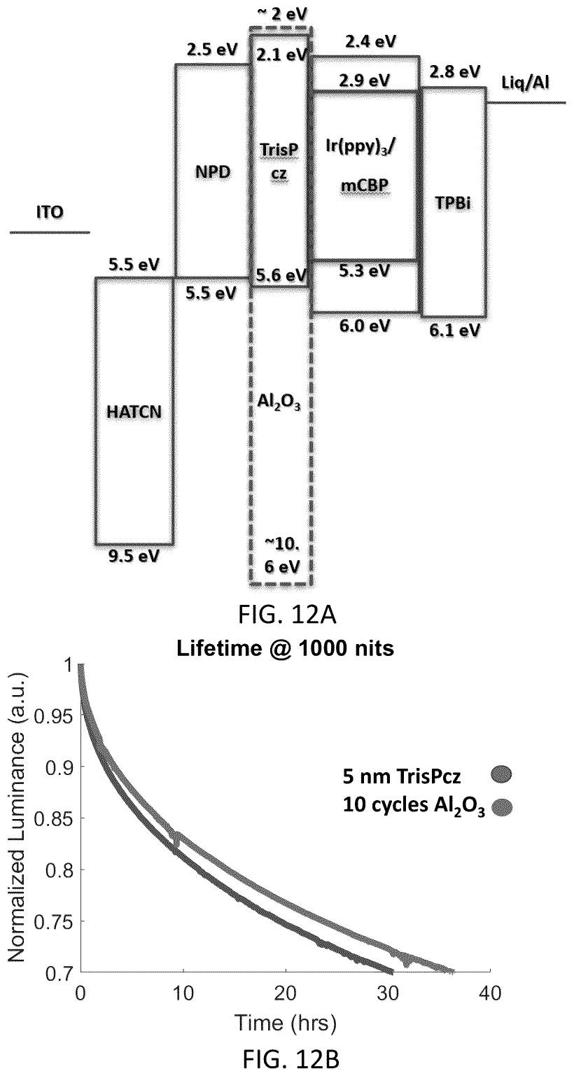

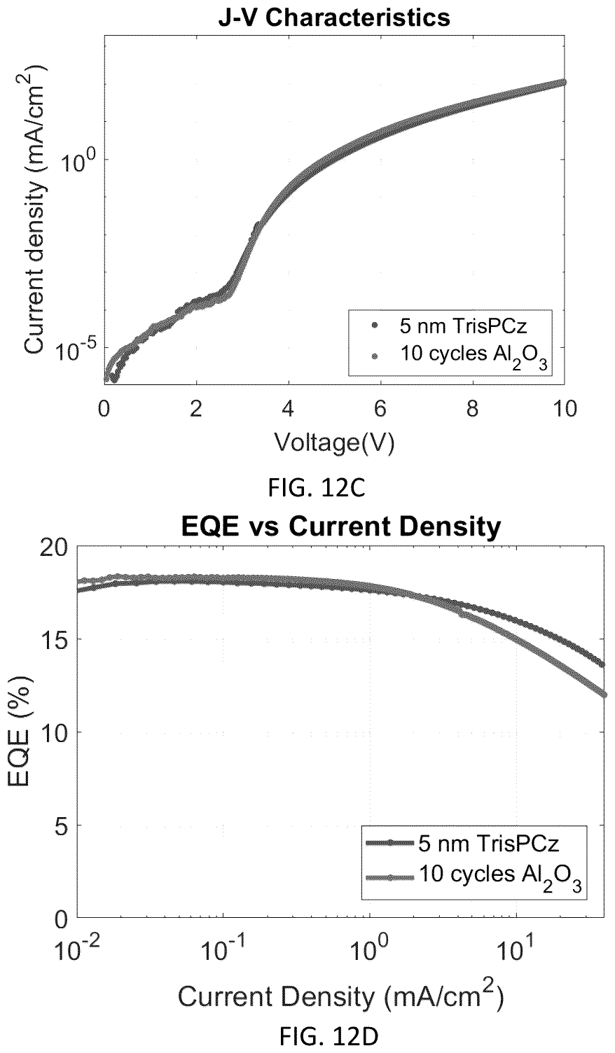

The device performance of a green OLED with conventional Tris-PCz blocker versus an ultra-thin Al₂O₃ blocker was then compared. FIGS. 12A-12D show the experimental performance results comparing these devices. FIG. 12A shows the experimental device structures and energy levels, FIG. 12B is a plot showing device lifetime at 1000 nits, FIG. 12C is a plot showing J-V characteristics, and FIG. 12D is a plot showing EQE vs Current Density. Both devices show similar JV characteristics. The EQE roll-off is slightly higher in the Al₂O₃ device. The lifetime of Al₂O₃ device is increased by about 20% compared to the Tris-PCz device.

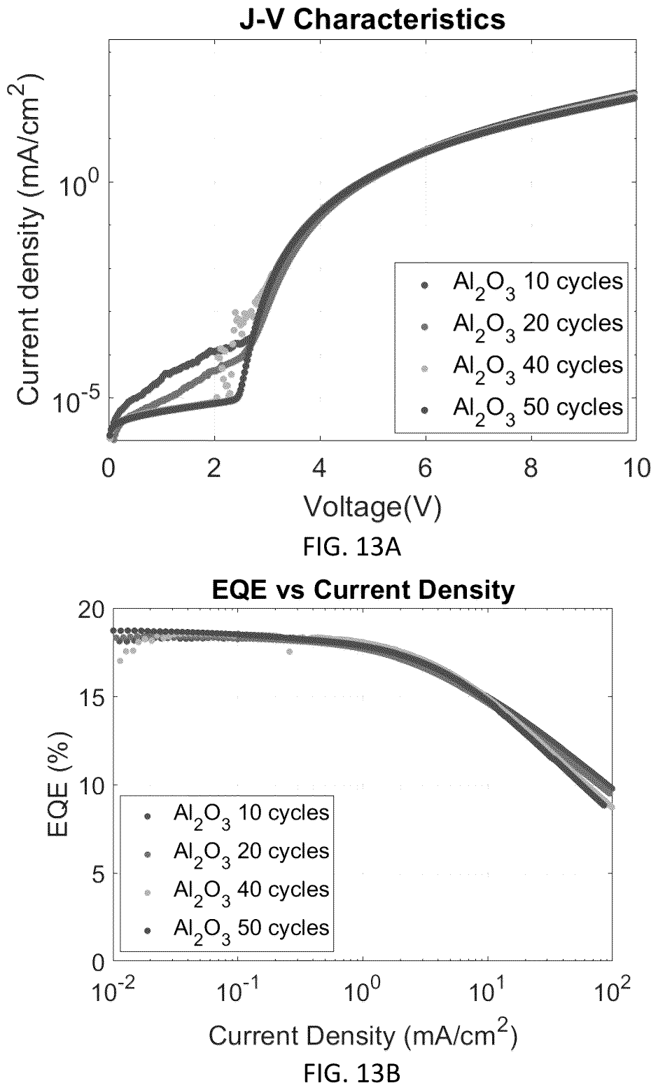

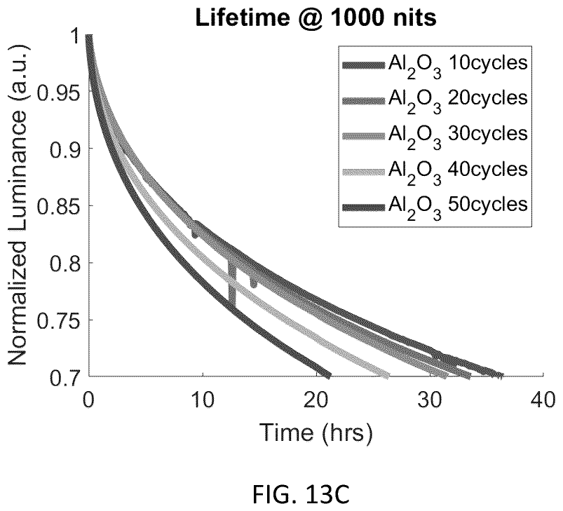

FIGS. 13A-13C are plots showing experimental results for devices based on increasing Al₂O₃ blocking layer thickness. FIG. 13A is a plot showing J-V characteristics, FIG. 13B is a plot showing EQE vs Current Density, and FIG. 13C is a plot showing device lifetime at 1000 nits. The off current reduces with increasing Al₂O₃ deposition cycles, but lifetime decreases with increasing Al₂O₃ deposition cycles. The enhancement of lifetime with Al₂O₃ blocker was lost after about 30 cycles.

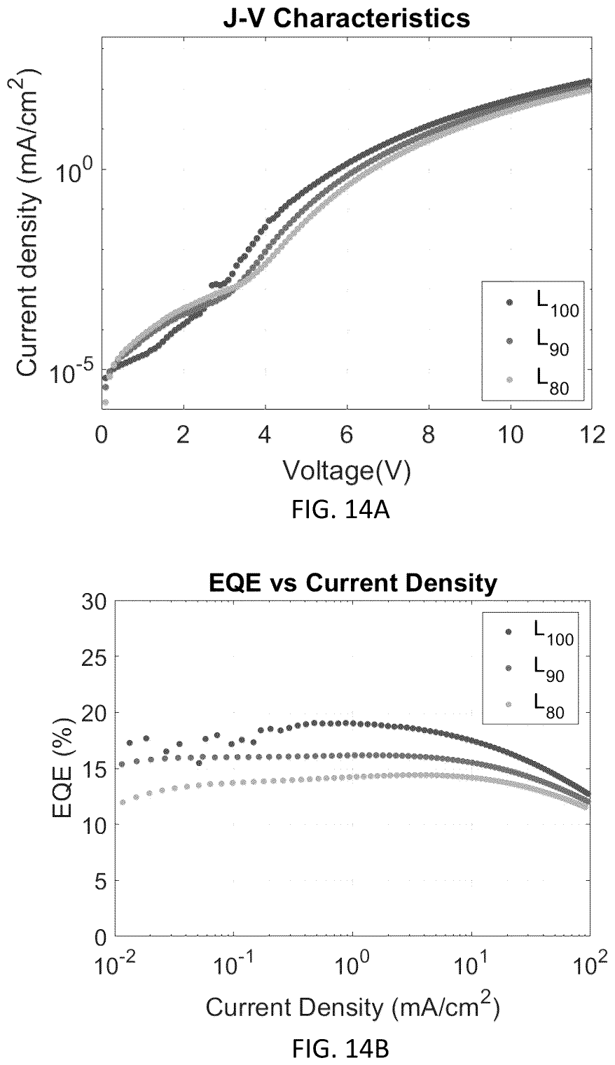

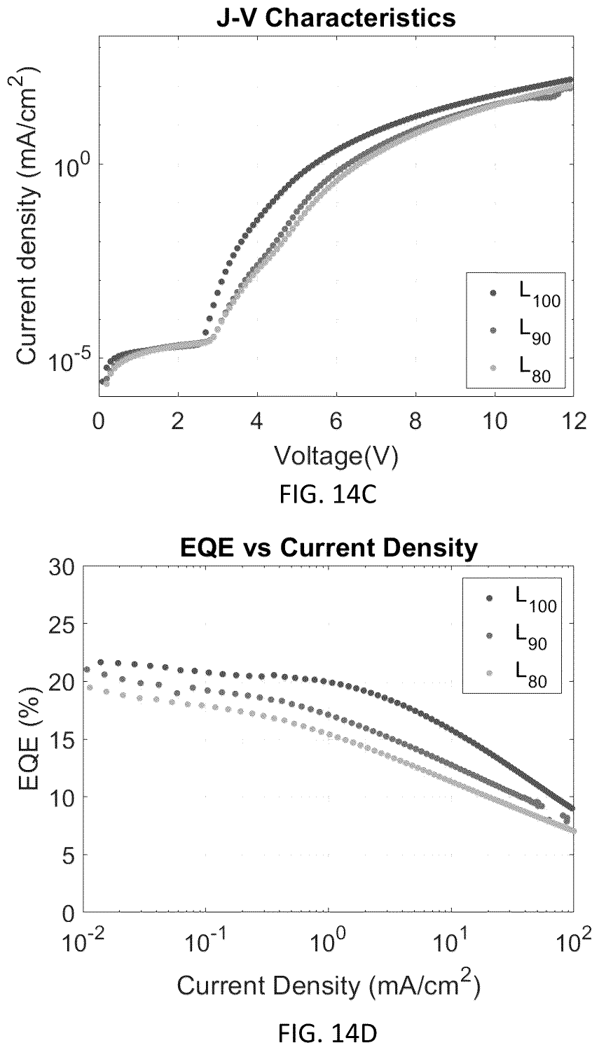

FIGS. 14A-14D are plots of J-V characteristics (FIG. 14A, FIG. 14C) and EQE vs Current Density (FIG. 14B, FIG. 14D) comparing experimental performance of devices utilizing TrisPCZ (FIGS. 14A-14B) and Al₂O₃(FIGS. 14C-14D) blocking layers detailing the reason behind the lifetime reduction. For the devices with Al₂O₃ blocking layers, the resistance increases drastically with aging. This effect becomes stronger with higher deposition cycles of Al₂O₃. Degradation of the organic-inorganic interface and charge build-up at the rough interface as seen from the AFM images causes annihilation leading to lifetime reduction.

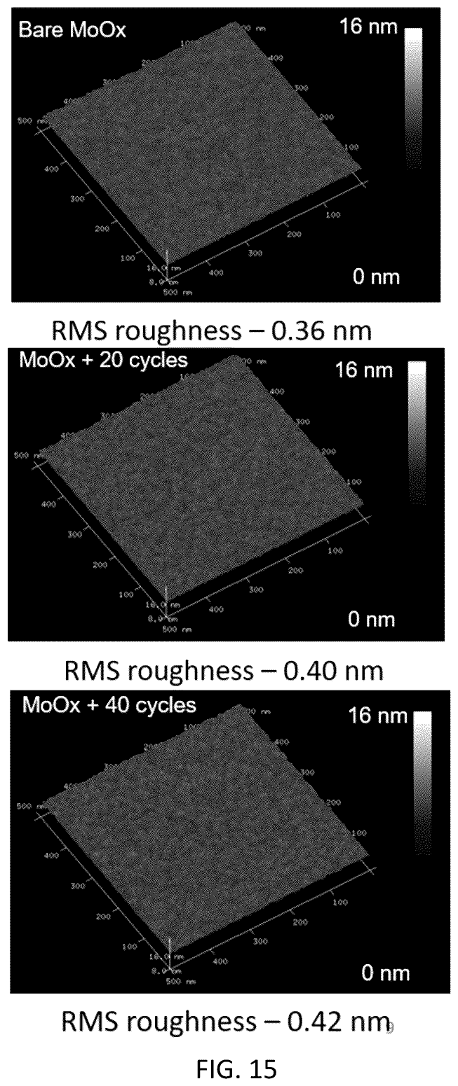

The lifetime reduction due to the rough interface provided motivation to look for ways to grow a uniform 2D layer of Al₂O₃. As shown in FIG. 15, Al₂O₃ grows as a neat 2D layer on top of MoOₓ with minimal increase in surface roughness.

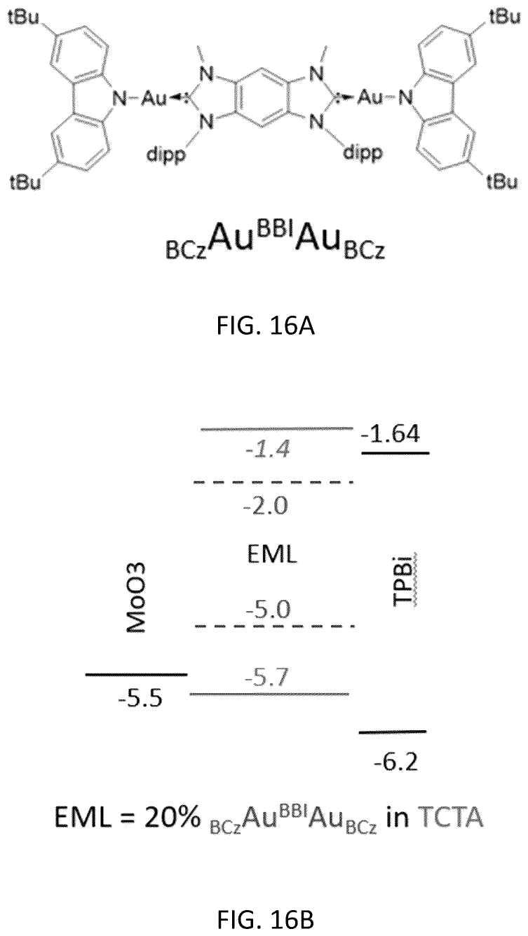

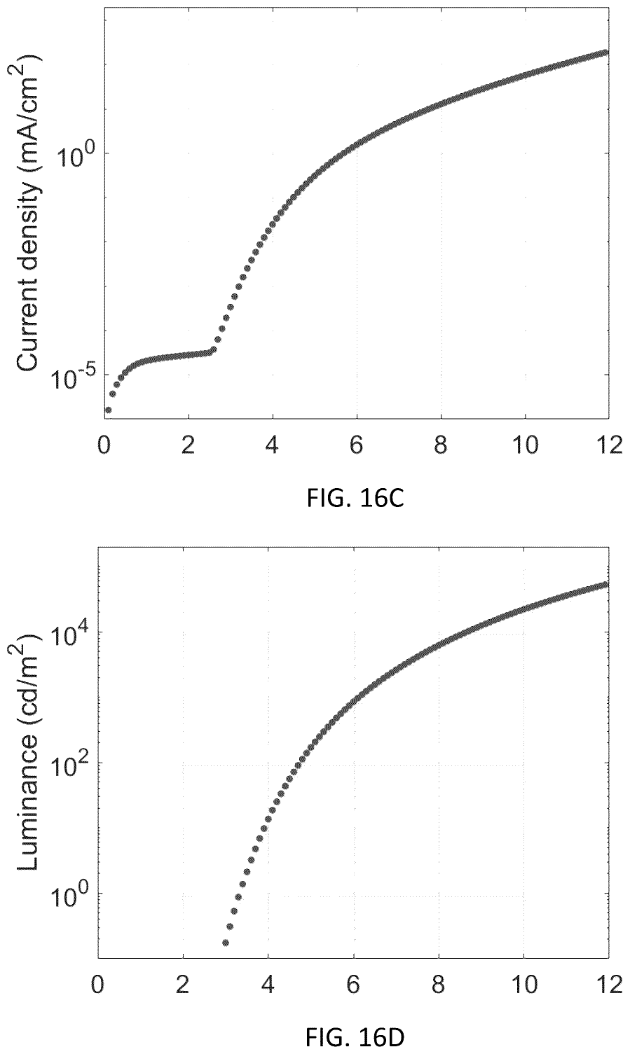

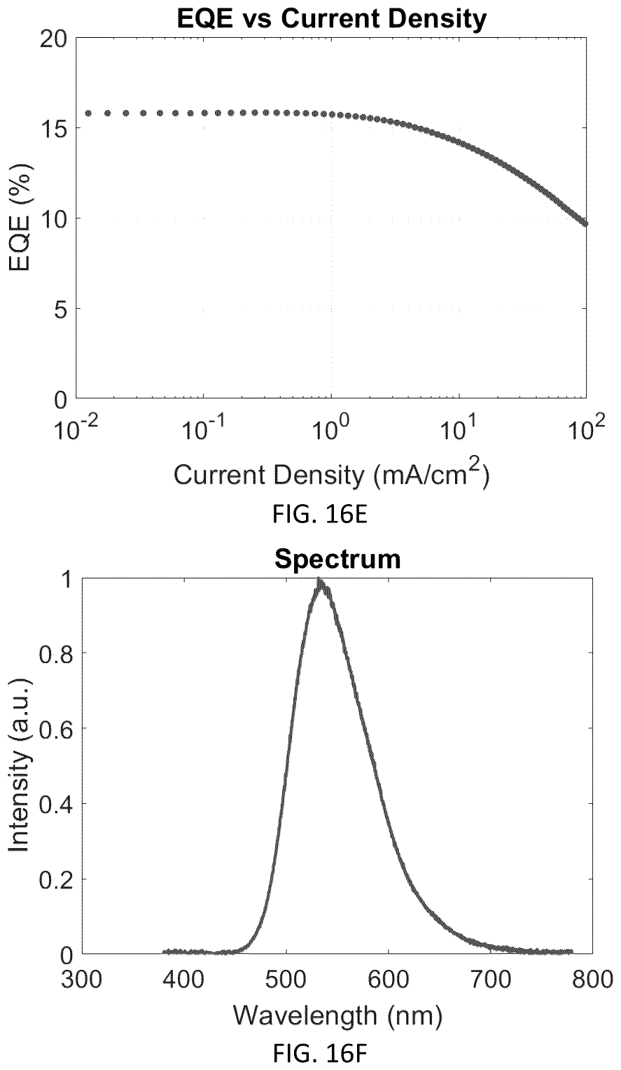

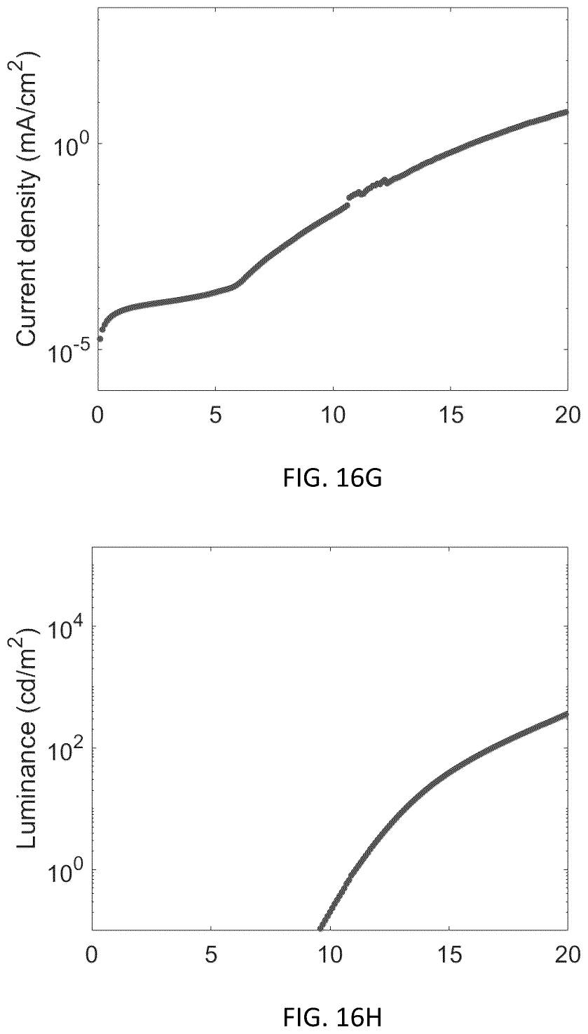

FIGS. 16A-16H depict details of experimental solution processed OLEDs with USC TADF dopant in accordance with some embodiments. FIGS. 16A-16B depict details of the devices, FIG. 16C is a plot depicting experimental current density for a control device, FIG. 16D us a plot depicting experimental luminance for the control device, FIG. 16E is a plot depicting EQE vs. Current Density for the control device, FIG. 16F is a spectrum plot for the control device, and FIGS. 16G-16H depict current density and luminance, respectively, for a device including a 2 nm ALD AL₂O₃ metal oxide blocking layer. Introduction of the Al₂O₃ blocking layer makes the device extremely resistive with very low luminance. A neat 2D layer of Al₂O₃ behaves as a complete insulator.

In summary Al₂O₃ grows as 3D islands on top of organic HTL. This layer reduces the off current in OLEDs with increasing thickness by blocking the shunt paths. However, due to charge build-up and annihilation at the rough interface, lifetime reduces with increasing thickness. Al₂O₃ grows as a uniform 2D layer on top of MoOₓ. This layer behaves as a complete insulator and does not let anything pass through. One example application is photodetectors with very low dark current.

The following publications are each incorporated herein by reference in their entirety:
1). C. Coburn, C. Jeong, and S. R. Forrest, ACS Photonics 5, (2018)
2). B. D'Andrade and J. J. Brown, in Defense, Security, Cockpit, and Future Displays II (2006).

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention.

1. An organic light emitting device (OLED), comprising:
a first electrode;
a charge transport layer above the first electrode;
a blocking layer above the charge transport layer, comprising a metal oxide;
an emissive layer above the metal oxide blocking layer; and
a second electrode above the emissive layer.

2. The OLED of claim 1, wherein the OLED is configured as a white OLED.

3. The OLED of claim 1, wherein the emissive layer comprises a stack of a plurality of sub-layers.

4. The OLED of claim 3, wherein the plurality of sub-layers comprise a green emissive sub-layer, a red emissive sub-layer, and a blue emissive sub-layer.

5. The OLED of claim 4, wherein the green emissive sub-layer has a thickness of 5 nm and comprises Ir(ppy)3:mCBP, the red emissive sub-layer has a thickness of 10 nm and comprises PQIr:mCBP, and the blue emissive sub-layer has a thickness of 10 nm and comprises Ir(iprpmi)3:mCBP.

6. The OLED of claim 1, wherein the blocking layer is deposited via an atomic layer deposition (ALD) tool.

7. The OLED of claim 1, where the blocking layer comprises HfO₂, Al₂O₃, ZrO₂, ZnO, or MgO.

8. The OLED of claim 1, where the blocking layer comprises a monolayer.

9. The OLED of claim 1, where the blocking layer has a roughness of less than 0.5 nm.

10. The OLED of claim 1, where the blocking layer has a thickness less than 5 nm.

11. The OLED of claim 1, further comprising a buffer layer between the blocking layer and the first electrode.

12. The OLED of claim 11, wherein the buffer layer is adjacent to the blocking layer.

13. The OLED of claim 12, wherein the buffer layer comprises MoOₓ.

14. The OLED of claim 1, wherein the blocking layer comprises a wide-bandgap material.

15. The OLED of claim 1, wherein the blocking layer has a valence band of −7 eV or deeper.

16. The OLED of claim 1, further comprising a second blocking layer between the emissive layer and the second electrode, comprising a metal oxide.

17. An organic light emitting device (OLED), comprising:
a first electrode;
a MoOₓ buffer layer above the first electrode;
a 2D blocking layer comprising metal oxide formed via atomic layer deposition (ALD) above and adjacent to the MoOₓ buffer layer;
an emissive layer above the blocking layer; and
a second electrode above the emissive layer.

18. The OLED of claim 17, wherein the OLED is configured as a white OLED.

19. The OLED of claim 17, where the blocking layer comprises HfO₂, Al₂O₃, ZrO₂, ZnO, or MgO.

20. (canceled)

21. An organic photodetector (OPD), comprising:
a first electrode;
a second electrode;
an active layer between the electrodes comprising an organic donor layer and an organic acceptor layer; and
a blocking layer between the active layer and one of the electrodes, comprising a metal oxide;
wherein on reverse bias the OPD produces a photocurrent in response to absorbed radiation, and wherein the dark current for a given reverse bias is lower than for an identical device without the blocking layer.
